(19) United States
(12) Patent Application Publication
(10) Pub. No.: US 2025/0236776 A1
(43) Pub. Date: Jul. 24, 2025

(54) HEAT DISSIPATION COMPONENT WITH ANISOTROPIC HEAT CONDUCTION AND METHOD OF FABRICATING THE SAME AND SEMICONDUCTOR DEVICE

(71) Applicant: Taiwan Semiconductor Manufacturing Company, Ltd., Hsinchu (TW)

(72) Inventors: Kai-Chieh Yang, Hsinchu (TW); Wei-Yen Woon, Taoyuan City (TW); Szuya LIAO, Hsinchu (TW)

(73) Assignee: Taiwan Semiconductor Manufacturing Company, Ltd., Hsinchu (TW)

(21) Appl. No.: 18/418,314

(22) Filed: Jan. 21, 2024

(51) Int. Cl. C09K 5/14; H01L 21/48; H01L 23/367; H01L 23/373

(52) U.S. Cl. CPC C09K 5/14; H01L 21/4871; H01L 23/3675; H01L 23/3733

(57) ABSTRACT

A heat dissipation component includes an anisotropic heat conduction material. The anisotropic heat conduction material includes a polymeric material and a thermal conductive material. First portions of the polymeric material are bonded by the thermal conductive material and form thermal conductive portions. Second portions of the polymeric material not bonded by the thermal conductive material form thermal insulation portions. The thermal conductive portions and the thermal insulation portions are alternately arranged.

### BACKGROUND

With technological advancements, the integration level of integrated circuits has been steadily increasing, resulting in dense circuit distribution within integrated circuits. However, the increased integration level has also given rise to thermal challenges. Inadequate heat dissipation may potentially lead to semiconductor component failures or even permanent damage. To address these issues, the use of heat sinks has become a common practice to significantly improve the thermal dissipation efficiency of integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method of fabricating a heat dissipation component in accordance with an embodiment of the present disclosure.

FIGS. 2A to 2B are cross-sectional views illustrating various stages of a manufacturing method of a dry film in accordance with an embodiment of the present disclosure.

FIG. 2C is a schematic diagram of a microstructure/nanostructure of the dry film in accordance with an embodiment of the present disclosure.

FIG. 3A is a schematic diagram of a polymeric material in accordance with an embodiment of the present disclosure.

FIG. 3B is a schematic diagram of a polymeric material in accordance with an embodiment of the present disclosure.

FIGS. 4A to 4B are cross-sectional views illustrating various stages of a manufacturing method of a dry film in accordance with an embodiment of the present disclosure.

FIG. 4C is a schematic diagram of a microstructure/nanostructure of the dry film in accordance with an embodiment of the present disclosure.

FIG. 5A is a schematic diagram of a copolymer of a polymeric material in accordance with an embodiment of the present disclosure.

FIG. 5B is a schematic diagram of a copolymer of a polymeric material in accordance with an embodiment of the present disclosure.

FIG. 5C is a schematic diagram of a copolymer of a polymeric material in accordance with an embodiment of the present disclosure.

FIG. 6A is a schematic diagram of a self-assembled composite material in accordance with an embodiment of the present disclosure.

FIG. 6B is a schematic diagram of a self-assembled composite material in accordance with an embodiment of the present disclosure.

FIG. 6C is a schematic diagram of a self-assembled composite material in accordance with an embodiment of the present disclosure.

FIGS. 7A to 7B are cross-sectional views illustrating various stages of a manufacturing method of a dry film in accordance with an embodiment of the present disclosure.

FIG. 7C is a schematic diagram of a microstructure/nanostructure of the dry film in accordance with an embodiment of the present disclosure.

FIGS. 8A to 8C are cross-sectional views illustrating various stages of a manufacturing method of a heat dissipation component in accordance with an embodiment of the present disclosure.

FIG. 9 is a cross-sectional view illustrating a semiconductor device in accordance with an embodiment of the present disclosure.

FIG. 10 is a cross-sectional view illustrating a semiconductor device in accordance with an embodiment of the present disclosure.

FIG. 11 is a cross-sectional view illustrating a semiconductor device in accordance with an embodiment of the present disclosure.

FIG. 12 is a cross-sectional view illustrating a heat dissipation component in accordance with an embodiment of the present disclosure.

FIGS. 13A to 13D are cross-sectional views illustrating various stages of a manufacturing method of a heat dissipation component in accordance with an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the structure in use or operation in addition to the orientation depicted in the figures. The apparatus may be otherwise oriented (rotated 90 degrees or at other orientations) and the spatially relative descriptors used herein may likewise be interpreted accordingly.

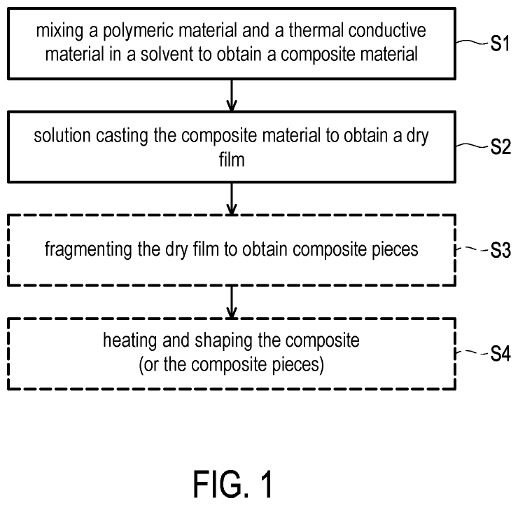

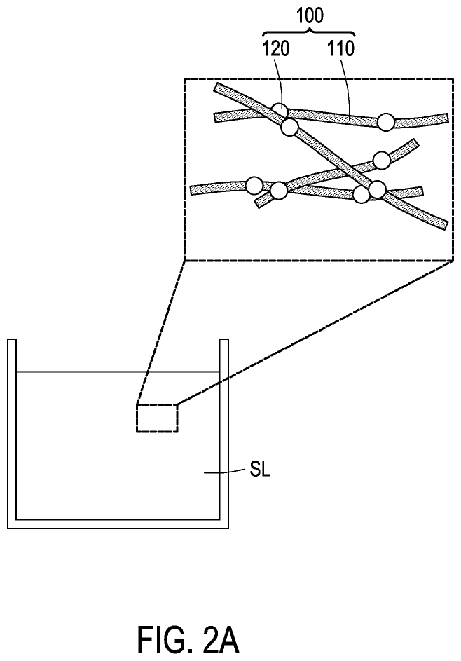

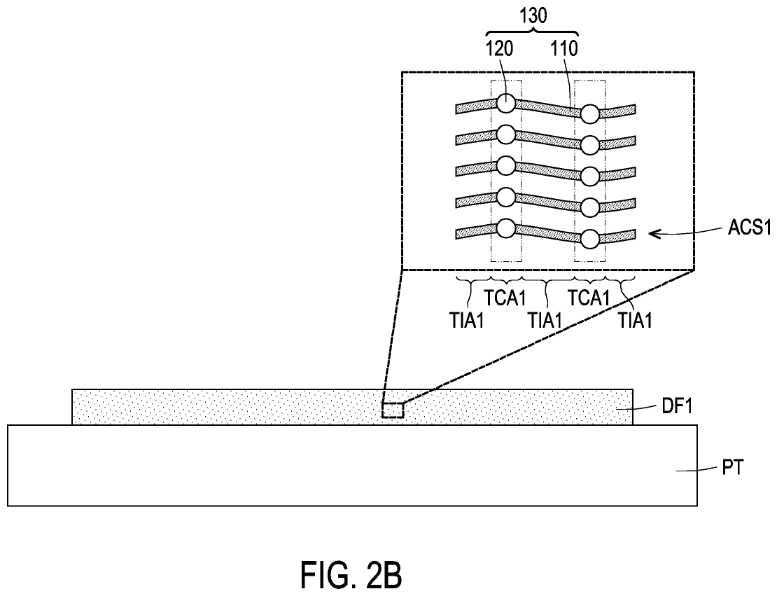

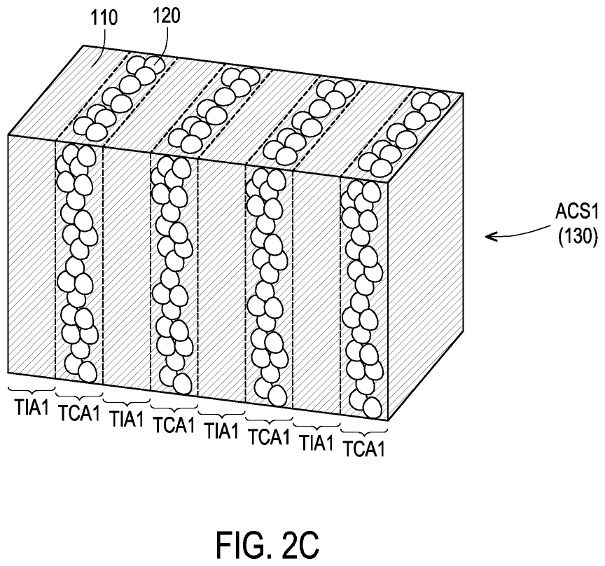

FIG. 1 is a flow chart of a method of fabricating a heat dissipation component in accordance with an embodiment of the present disclosure. FIGS. 2A to 2B are cross-sectional views illustrating various stages of a manufacturing method of a dry film DF1 in accordance with an embodiment of the present disclosure. FIG. 2C is a schematic diagram of a microstructure/nanostructure of the dry film DF1 in accordance with an embodiment of the present disclosure. Referring to FIG. 2A and step S1 in FIG. 1, a polymeric material 110 and a thermal conductive material 120 are mixed in a solvent SL to obtain a composite material 100. In some embodiments, the polymeric material 110 includes homopolymer. In alternative embodiments, the polymeric material 110 includes polymer blends or copolymer.

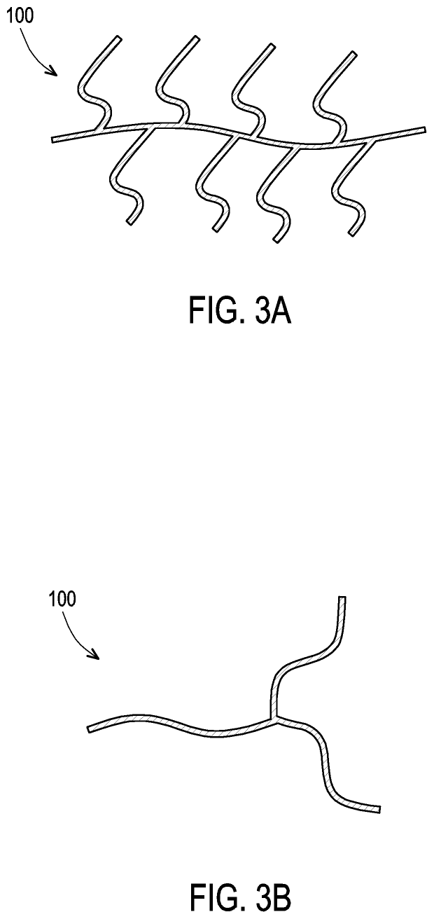

In some embodiments, the polymeric material 110 includes polyethylene, poly(vinylidene fluoride), polylactide, polydiacetylene, polycarbonate, polyolefin, polythiophene, poly(3-hexylthiophene), polyurethane, fluorene polyester, polyimide or divinyltetramethyldisiloxane-bis(benzocyclobutene). In some embodiments, the polymeric material 110 has a linear architecture. In alternative embodiments, the polymeric material 110 may have a grafted architecture (as shown in FIG. 3A) or a star architecture (as shown in FIG. 3B). In an embodiment in which the polymeric material has a grafted architecture, the control of the grafting location and grafting density of a grafted polymer may be achieved using the functionalized linking groups. These functionalized linking groups may be stimulated by an external source.

In some embodiments, the thermal conductive material 120 includes metal (e.g., copper, silver), graphene, ceramics (e.g., SiO₂, hexagonal BN, SiC), diamond, other suitable thermal conductive material or a combination thereof. In some embodiments, the thermal conductive material 120 includes nanoparticles, nanotubes, nanoplates, the like or a combination thereof. For example, the thermal conductive material 120 includes metal particles such as copper particles and silver particles. In some embodiments, the size (e.g., width, length or particle size) of the thermal conductive material 120 ranges from 1 nm to 50 nm. The blending ratio of the thermal conductive material 120 and the polymeric material 110 may be in a range of 50-70 vol %, but the disclosure is not limited thereto. Within the above range, the final composite material may have desirable flexibility and thermal conductivity.

In some embodiments, the thermal conductive material 120 is bonding to a specific location of the polymeric material 110. For instance, the thermal conductive material 120 attaches to a certain molecular segment of the polymeric material 110 or to a terminal of the polymeric material 110, while other portions of the polymeric material 110 are less prone to binding with the thermal conductive material 120. In some embodiments, the desired effect is achieved by incorporating functional groups into the polymeric material 110 that readily bonds with the thermal conductive material 120. The functional groups may include thiol, hydroxyl, amine or the like. The thermal conductive material 120 may be bonding with these functional groups, while the portions of the polymeric material 110 lacking functional groups are less prone to be bonding with the thermal conductive material 120. In some embodiments, the thermal conductive material 120 is bonding to the polymeric material 110 through van der Waals forces, hydrogen bonds, or other bonding mechanisms. As shown in FIG. 2A, there may be more than one thermal conductive material 120 bonding to one polymeric material 110. However, the disclosure is not limited thereto.

In some embodiments, the polymeric material 110 and the thermal conductive material 120 are dissolved and/or dispersed in a solvent SL. The solvent SL includes an organic solvent, such as acetone, ether, methanol, ethanol, benzene, chloroform, n-hexane, acetic acid, ethyl acetate, butyl acetate, dichloromethane, the like or a combination thereof. In some embodiments, at least one co-solvent is also used to improve solubility and control evaporation rate. The polymeric material 110 and the thermal conductive material 120 may be separately or jointly added to the solvent SL and thoroughly mixed, such that the thermal conductive material 120 may bond to the polymeric material 110. Because the thermal conductive material 120 and the polymeric material 110 may move freely in the solvent SL, the thermal conductive material 120 have a higher probability to bond specific locations of the polymeric material 110, such as specific molecular segments, specific functional groups, or specific terminals. In some embodiments, the addition of dispersants in the solvent SL may facilitate the bonding of the thermal conductive material 120 with the polymeric material 110.

Referring to FIG. 2B and step S2 in FIG. 1, a dry film DF1 is formed by the composite material 100. In some embodiments, the dry film DF1 is formed by subjecting the composite material 100 to solution casting, spread coating, spin coating, the like or combinations thereof. For example, the solvent SL containing the composite material 100 is applied onto a platform PT using a method such as roller coating, brushing, spraying, tape casting, immersion, or the like. Subsequently, the solvent SL is evaporated, resulting in the formation of the dry film DF1. In some embodiments, a thickness of the dry film DF1 is less than 0.5 mm. For example, the thickness of the dry film DF1 is in a range from 0.1 mm to 0.5 mm. In some embodiments, the platform PT is a Teflon paper or the like.

During the evaporation of the solvent SL, the polymeric material 110 and the thermal conductive material 120 may self-assemble to form an anisotropic heat conduction material 130. As shown in FIGS. 2B and 2C, the polymeric material 110 is continuously and orderly arranged along a first direction, to form the anisotropic heat conduction material 130. The first direction is a vertical direction or a substantially vertical direction, for example. The orientation of the polymeric material 110 may be controlled during the solution casting with fast kinetic. In some embodiments, the polymeric material 110 may be partially crystallized for better heat transfer. The thermal conductive material 120 may be well-ordered for anisotropic heat conduction. In some embodiments, the anisotropic heat conduction material 130 includes a plurality of thermal conductive portions TCA1 and a plurality of thermal insulation portions TIA1 alternately arranged along a second direction. In some embodiments, the thermal conductive portions TCA1 are also referred to first lamellar portions and the thermal insulation portions TIAL are also referred to second lamellar portions, and the thermal conductive portions TCA1 and the thermal insulation portions TIA1 are in a lamellar arrangement. The second direction is a horizontal direction or a substantially horizontal direction, for example. The thermal conductive portions TCA1 are formed by the thermal conductive material 120 and the segments (e.g., portions) of the polymeric material 110 bonded by the thermal conductive material 120, and the thermal insulation portions TIAL are formed by the segments (e.g., portions) of the polymeric material 110 not bonded by the thermal conductive material 120, for example. In other words, since the polymeric material 110 is the skeleton of the anisotropic heat conduction material 130, the polymeric material 110 forms both the thermal conductive portions TCA1 and the thermal insulation portions TIA1 while the thermal conductive material 120 only forms the thermal conductive portions TCA1. In some embodiments, the thickness of the thermal conductive portions TCA1 is in a range from 5 nm to 100 nm, and the thickness of the thermal insulation portions TIA1 is in a range from 5 nm to 100 nm.

In some embodiments, due to the differences in surface energy, hydrophilic/hydrophobic properties, energy gaps, or other characteristics, portions of the polymeric material 110 bonded by the thermal conductive material 120 and portions of the polymeric material 110 not bonded by the thermal conductive material 120 tend to separately aggregate/accumulate, so as to form a lamellae structure as depicted in FIG. 2C.

In some embodiments, the thermal conductive portions TCA1 with the thermal conductive material 120 exhibit a higher thermal conductivity. On contrary, the thermal insulation portions TIA1 without the thermal conductive material 120 have a lower thermal conductivity. By this arrangement, heat may easily propagate within the thermal conductive portions TCA1 but have limited transmission through the thermal insulation portions TIA1, so that the anisotropic heat conduction material 130 may have anisotropic heat conduction structures ACS1 and thus anisotropic thermal conductivity. In some embodiments, the formed dry film DF1 has a high thermal conductivity (such as, but not limited to, 100 Wm⁻¹K⁻¹ to 250 Wm⁻¹K⁻¹) in a first direction (e.g., a direction substantially perpendicular to the bottom surface of the dry film DF1). In some embodiments, the dry film DF1 has a low thermal conductivity (such as, but not limited to, lower than or equal to about 100 Wm⁻¹K⁻¹) in a second direction (e.g., a direction substantially parallel to the bottom surface of the dry film DF1) different from the first direction. In some embodiments, the difference between the maximum thermal conductivity (in the first direction) and the minimum thermal conductivity (in the second direction) of the dry film DF1 is greater than 10 Wm⁻¹K⁻¹, 20 Wm⁻¹K⁻¹, 30 Wm⁻¹K⁻¹ or more.

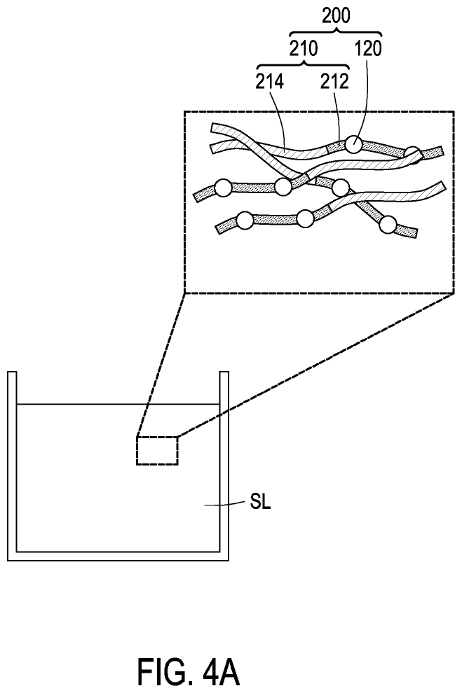

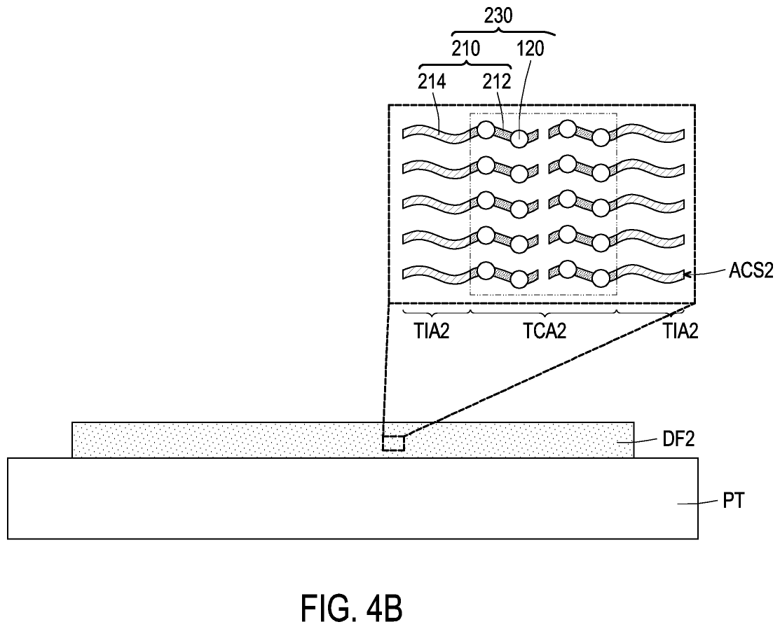

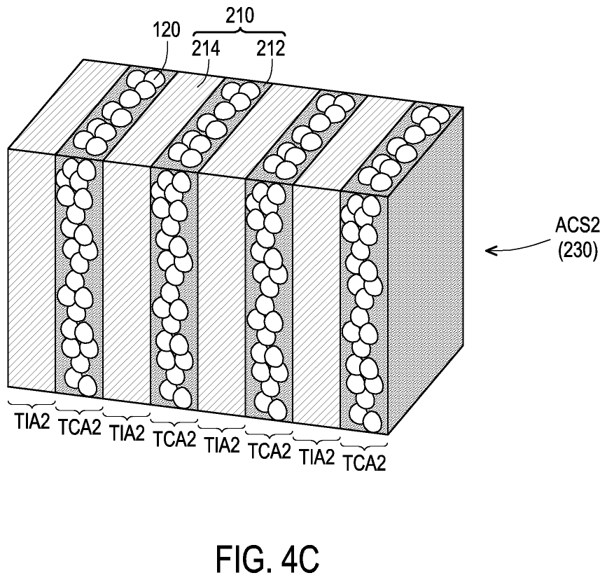

FIGS. 4A to 4B are cross-sectional views illustrating various stages of a manufacturing method of a dry film DF2 in accordance with an embodiment of the present disclosure. FIG. 4C is a schematic diagram of a microstructure/nanostructure of the dry film DF2 in accordance with an embodiment of the present disclosure. The main difference between the embodiments of FIGS. 4A to 4C and the embodiments of FIGS. 2A to 2C lies in that the polymeric material 210 includes copolymer and thus the same or similar descriptions may refer to the embodiments of FIGS. 2A to 2C and omitted herein.

Referring to FIG. 4A and step S1 in FIG. 1, a polymeric material 210 and a thermal conductive material 120 are mixed in a solvent SL to obtain a composite material 200. In some embodiments, the polymeric material 210 includes copolymer, and the copolymer includes a first structural unit 212 and a second structural unit 214 different from the first structural unit 212. In some embodiments, the first structural unit 212 is also referred to as a first portion of the polymeric material 210, and the second structural unit 212 is also referred to as a second portion of the polymeric material 210.

In some embodiments, one of the first structural unit 212 and the second structural unit 214 includes a conjugated crystalline polymer with π bonds, and another one of the first structural unit 212 and the second structural unit 214 includes a random block. In some embodiments, the conjugated crystalline polymer with bonds includes poly(alkoxyphenylenevinylene), poly(p-phenylene) (PPP), polyacetylene (PA) or the like. In some embodiments, the random block includes polystyrene, poly(oxyethylene), or the like. Generally, the conjugated crystalline polymers with π bonds are more rigid, while the random blocks are more flexible. By combining the conjugated crystalline polymers with the random blocks, it is possible to achieve better orientation in the resulting anisotropic heat conduction structures (referring to FIG. 4C).

The first structural unit 212 and the second structural unit 214 may possess different properties such as hydrophilic/hydrophobic properties, different energy gaps, or other distinct characteristics. Due to the differences, the first structural unit 212 is compatible with the thermal conductive material 120, while the second structural unit 214 is not compatible with the thermal conductive material 120. That is, the thermal conductive material 120 is bonding to the first structural unit 212 rather than bonding to the second structural unit 214. In some embodiments, the thermal conductive material 120 is bonding to the first structural unit 212 through van der Waals forces, hydrogen bonds, or other bonding mechanisms.

In some embodiments, there is no direct bonding between the thermal conductive material 120 and the first structural unit 212 or the second structural unit 214. Since the thermal conductive material 120 is more compatible with the first structural unit 212, the thermal conductive material 120 tends to move near the first structural unit 212 (e.g., a terminal of the first structural unit 212) and aggregates around the first structural unit 212 due to the cohesive forces between the thermal conductive material 120 (e.g., between the particles). In such embodiments, when adjacent first structural units 212 come into contact and/or bond with each other through self-assembly, the thermal conductive material 120 also aggregates in the same region as the first structural units 212.

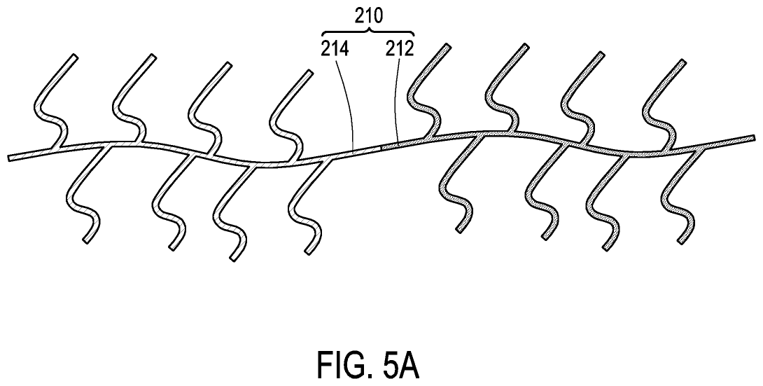

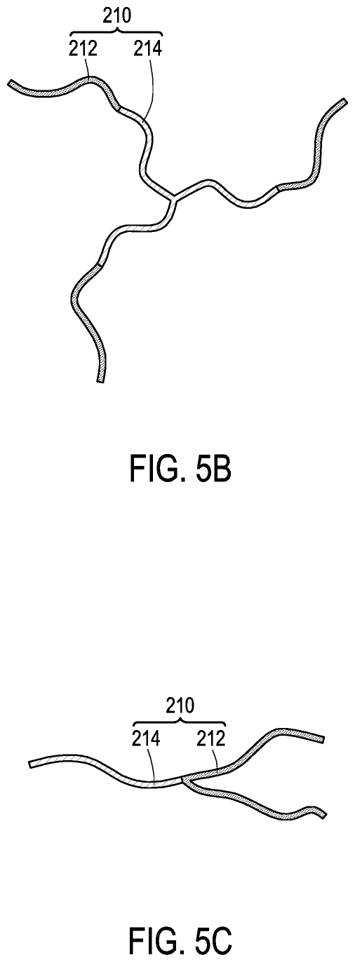

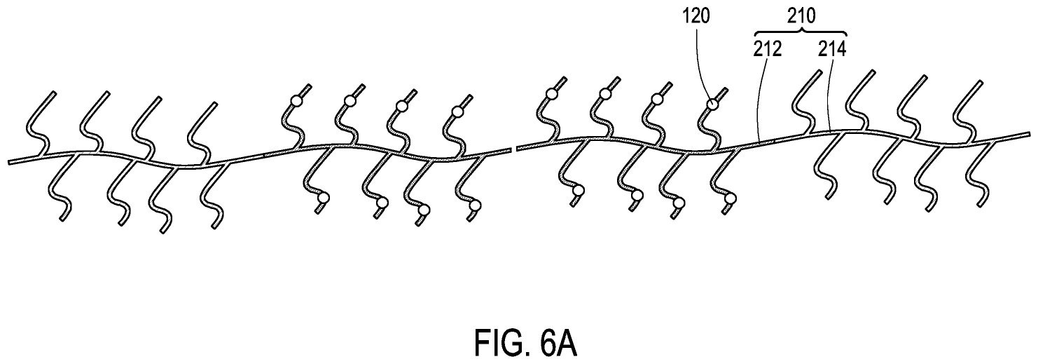

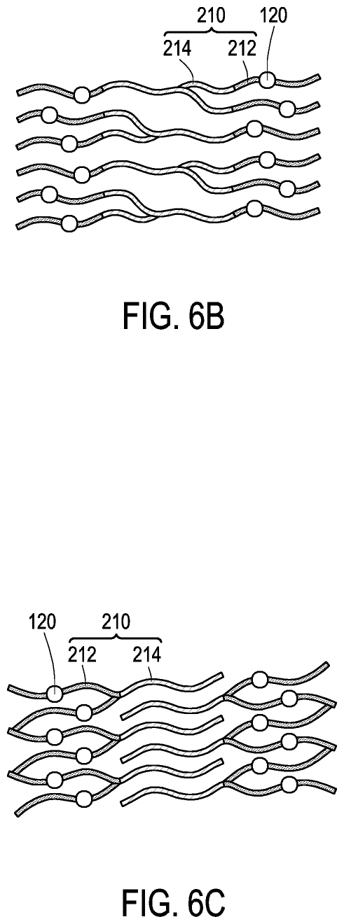

In FIGS. 4A to 4C, the polymeric material 210 is illustrated as a copolymer with a linear architecture. In alternative embodiments, the polymeric material 210 may have a grafted architecture (as shown in FIGS. 5A and 6A), a star architecture (as shown in FIGS. 5B and 6B), or a miktoarm star architecture (as shown in FIGS. 5C and 6C). The grafting density and grafting location within the copolymer may be pre-designed using functionalized linking groups that are responsive to an external source. Controlling the grafting density and grafting location may facilitate achieving specific mechanical properties. In some embodiments, the grafted copolymer may include poly(p-phenylene)-polystyrene or the like. It should be noted that, in the star architecture of FIG. 5B, the first structural unit 212 is located at the center of the structure and the second structural unit 214 is located at the periphery of the structure, but this disclosure is not limited thereto. In alternative embodiments, the second structural unit 214 may be located in the center of the structure and the first structural unit 212 is located at the periphery of the structure. In some embodiments, the thermal conductive material 120 are similar to or the same as the thermal conductive material 120 mentioned above, so the detailed descriptions thereof are omitted herein.

In some embodiments, as shown in FIG. 4A, the polymeric material 210 is dissolved and/or dispersed in a solvent SL. The solvent SL includes an organic solvent, such as acetone, ether, methanol, ethanol, benzene, chloroform, n-hexane, acetic acid, ethyl acetate, butyl acetate, dichloromethane, the like or a combination thereof. The polymeric material 210 and the thermal conductive material 120 may be separately or jointly added to the solvent SL and thoroughly mixed, such that the thermal conductive material 120 may bond to the first structural units 212. Because the thermal conductive material 120 and the copolymer (i.e., first and second structural units 212 and 214) may move freely in the solvent SL, the thermal conductive material 120 have a higher probability to bond the first structural units 212. In some embodiments, the addition of dispersants in the solvent SL may facilitate the bonding of the thermal conductive material 120 with the copolymer.

Referring to FIG. 4B and step S2 in FIG. 1, a dry film DF2 is formed by the composite material 200. In some embodiments, the dry film DF2 is formed by subjecting the composite material 200 to solution casting. For example, the solvent SL containing the composite material 200 is applied onto a platform PT using a method such as roller coating, brushing, spraying, tape casting, immersion, or the like. Subsequently, the solvent SL is evaporated, resulting in the formation of the dry film DF2. In some embodiments, a thickness of the dry film DF2 is less than 0.5 mm. For example, the thickness of the dry film DF2 is in a range from 0.1 mm to 0.5 mm. In some embodiments, the platform PT is a Teflon paper or the like.

During the evaporation of the solvent SL, the polymeric material 210 (e.g., first and second structural units 212, 214) and the thermal conductive material 120 may self-assemble to form an anisotropic heat conduction material 230. As shown in FIGS. 4B and 4C, the polymeric material 210 (e.g., first and second structural units 212, 214) is continuously and orderly arranged along a first direction, to form the anisotropic heat conduction material 230. The first direction is a vertical direction or a substantially vertical direction, for example. In some embodiments, since the first structural units 212 have similar property, the first structural units 212 are arranged adjacently. For example, a terminal of the first structural unit 212 is immediately adjacent to a terminal of another first structural unit 212. The orientation of the polymeric material 210 may be controlled via solution casting with fast kinetic. In some embodiments, the polymeric material 210 may be partially crystallized for better heat transfer. The thermal conductive material 120 may be well-ordered for anisotropic heat conduction. In some embodiments, the anisotropic heat conduction material 230 includes a plurality of thermal conductive portions TCA2 and a plurality of thermal insulation portions TIA2 alternately arranged along a second direction. The second direction is a horizontal direction or a substantially horizontal direction, for example. In some embodiments, the thermal conductive portions TCA2 are also referred to first lamellar portions and the thermal insulation portions TIA2 are also referred to second lamellar portions, and the thermal conductive portions TCA2 and the thermal insulation portions TIA2 are in a lamellar arrangement. The thermal conductive portions TCA2 are formed by the thermal conductive material 120 and the first structural units 212 bonded by the thermal conductive material 120, and the thermal insulation portions TIA2 are formed by the second structural units 214 not bonded by the thermal conductive material 120, for example. In some embodiments, the thickness of the thermal conductive portions TCA2 is in a range from 5 nm to 100 nm, and the thickness of the thermal insulation portions TIA2 is in a range from 5 nm to 100 nm.

In some embodiments, due to the differences in surface energy, hydrophilic/hydrophobic properties, energy gaps, or other characteristics, the first structural unit 212 bonded by the thermal conductive material 120 and the second structural unit 214 not bonded by the thermal conductive material 120 tend to separately aggregate/accumulate, so as to form a lamellae structure as depicted in FIG. 4C.

In some embodiments, the thermal conductive portions TCA2 with the thermal conductive material 120 exhibit a higher thermal conductivity. On contrary, the thermal insulation portions TIA2 without the thermal conductive material 120 have a lower thermal conductivity. By this arrangement, heat may easily propagate within the thermal conductive portions TCA2 but have limited transmission through the thermal insulation portions TIA2, so that the anisotropic heat conduction material 230 may have anisotropic heat conduction structures ACS2 and thus anisotropic thermal conductivity. In some embodiments, the dry film DF2 has a high thermal conductivity (such as, but not limited to, 100 Wm⁻¹K⁻¹ to 250 Wm⁻¹K⁻¹) in a first direction (e.g., a direction substantially perpendicular to the bottom surface of the dry film DF2). In some embodiments, the dry film DF2 has a low thermal conductivity (such as, but not limited to, lower than or equal to about 100 Wm⁻¹K⁻¹) in a second direction (e.g., a direction substantially parallel to the bottom surface of the dry film DF2) different from the first direction. In some embodiments, the difference between the maximum thermal conductivity (in the first direction) and the minimum thermal conductivity (in the second direction) of the dry film DF2 is greater than 10 Wm⁻¹K⁻¹, 20 Wm⁻¹K⁻¹, 30 Wm⁻¹K⁻¹ or more.

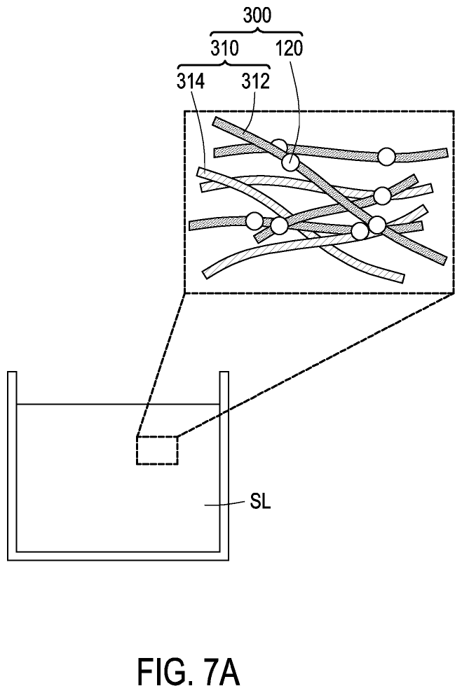

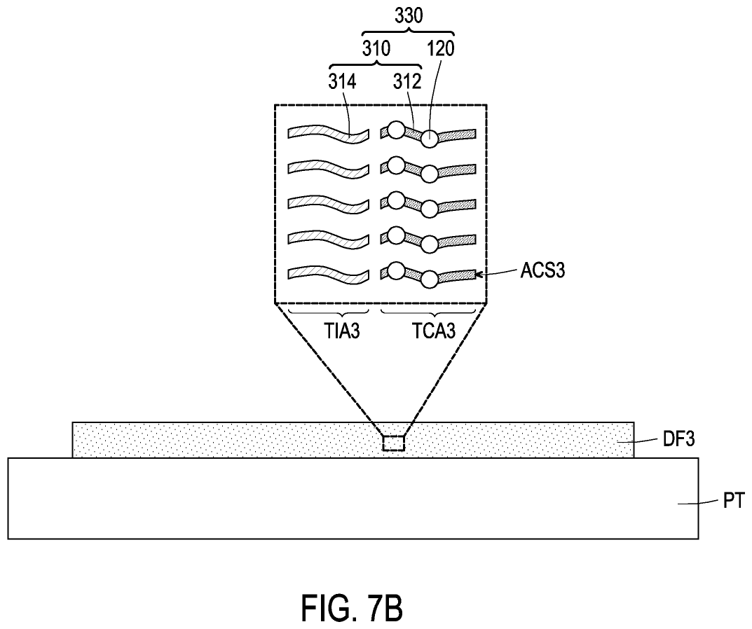

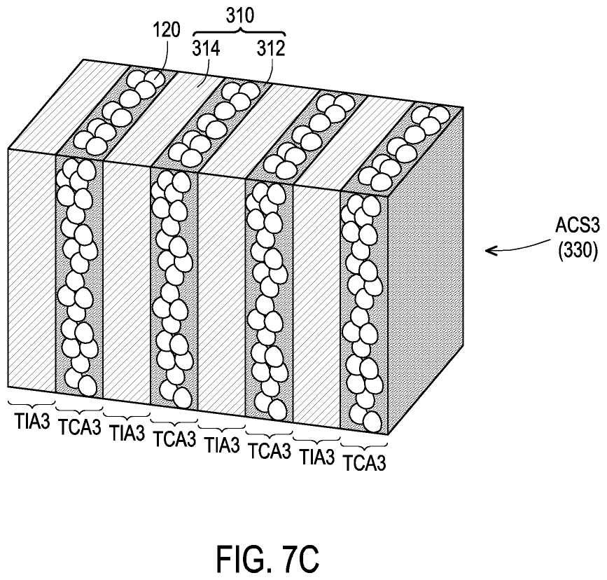

FIGS. 7A to 7B are cross-sectional views illustrating various stages of a manufacturing method of a dry film DF3 in accordance with an embodiment of the present disclosure. FIG. 7C is a schematic diagram of a microstructure/nanostructure of the dry film DF3 in accordance with an embodiment of the present disclosure. The main difference between the embodiments of FIGS. 7A to 7C and the embodiments of FIGS. 2A to 2C lies in that the polymeric material 310 includes polymer blends and thus the same or similar descriptions may refer to the embodiments of FIGS. 2A to 2C and not omitted herein.

Referring to FIG. 7A and step S1 in FIG. 1, a polymeric material 310 and a thermal conductive material 120 are mixed in a solvent SL to obtain a composite material 300. In some embodiments, the polymeric material 310 includes polymer blends with a first polymer 312 and a second polymer 314. In some embodiments, the first polymer 312 is also referred to as a first portion of the polymeric material 310, and the second polymer 314 is also referred to as a second portion of the polymeric material 310. In some embodiments, the first polymer 312 and the second polymer 314 respectively have a linear architecture. In alternative embodiments, the first polymer 312 and the second polymer 314 respectively have a grafted architecture, a star architecture or a miktoarm star architecture.

The first polymer 312 is different from and would not polymerize with the second polymer 314. In some embodiments, the first polymer 312 and the second polymer 314 possess different properties such as hydrophilic/hydrophobic properties, different energy gaps, or other distinct characteristics. Due to the differences, the first polymer 312 is compatible with the thermal conductive material 120, while the second polymer 314 is not compatible with the thermal conductive material 120. That is, the thermal conductive material 120 are bonding to the first polymer 312 rather than bonding to the second polymer 314. In some embodiments, the thermal conductive material 120 is bonding to the first polymer 312 through van der Waals forces, hydrogen bonds, or other bonding mechanisms.

In some embodiments, there is no direct bonding between the thermal conductive material 120 and the first polymer 312 or the second polymer 314. Since the thermal conductive material 120 is more compatible with the first polymer 312, the thermal conductive material 120 tend to move near the first polymer 312 (e.g., a terminal of the first polymer 312) and aggregate around the first polymer 312 due to the cohesive forces between the thermal conductive material 120. In such embodiments, when adjacent first polymers 312 come into contact and/or bond with each other through self-assembly, the thermal conductive material 120 aggregates in the same region as the first polymers 312.

In some embodiments, as shown in FIG. 7A, the polymeric material 310 is dissolved and/or dispersed in a solvent SL. The solvent SL includes an organic solvent, such as acetone, ether, methanol, ethanol, benzene, chloroform, n-hexane, acetic acid, ethyl acetate, butyl acetate, dichloromethane, the like or a combination thereof. The polymeric material 310 and the thermal conductive material 120 may be separately or jointly added to the solvent SL and thoroughly mixed, such that the thermal conductive material 120 may bond to the first polymer 312 of the polymeric material 210. Because the thermal conductive material 120 and the first polymer 312 may move freely in the solvent SL, the thermal conductive material 120 have a higher probability to bond the first polymer 312. In some embodiments, the addition of dispersants in the solvent SL may facilitate the bonding of the thermal conductive material 120 with the copolymer.

Referring to FIG. 7B and step S2 in FIG. 1, a dry film DF3 is formed by the composite material 300. In some embodiments, the dry film DF3 is formed by subjecting the composite material 300 to solution casting. For example, the solvent SL containing the composite material 300 is applied onto a platform PT using a method such as roller coating, brushing, spraying, tape casting, immersion, or the like. Subsequently, the solvent SL is evaporated, resulting in the formation of the dry film DF3. In some embodiments, a thickness of the dry film DF3 is less than 0.5 mm. For example, the thickness of the dry film DF3 is in a range from 0.1 mm to 0.5 mm. In some embodiments, the platform PT may be a Teflon paper or other suitable materials.

During the evaporation of the solvent SL, the polymeric material 310 and the thermal conductive material 120 may self-assemble to form an anisotropic heat conduction material 230. As shown in FIGS. 7B and 7C, the polymeric material 310 (e.g., first and second polymers 312, 314) is continuously and orderly arranged along a first direction, to form the anisotropic heat conduction material 330. The first direction is a vertical direction or a substantially vertical direction, for example. The orientation of the polymeric material 310 may be controlled via solution casting with fast kinetic. In some embodiments, the polymeric material 310 may be partially crystallized for better heat transfer. The thermal conductive material 120 may be well-ordered for anisotropic heat conduction. In some embodiments, the anisotropic heat conduction material 330 includes a plurality of thermal conductive portions TCA3 and a plurality of thermal insulation portions TIA3 alternately arranged along a second direction. The second direction is a horizontal direction or a substantially horizontal direction, for example. The thermal conductive portions TCA3 are formed by the thermal conductive material 120 and the first polymers 312 bonded by the thermal conductive material 120, and the thermal insulation portions TIA3 are formed by the second polymers 314 not bonded by the thermal conductive material 120, for example. In some embodiments, the thermal conductive portions TCA3 are also referred to first lamellar portions and the thermal insulation portions TIA3 are also referred to second lamellar portions, and the thermal conductive portions TCA3 and the thermal insulation portions TIA3 are in a lamellar arrangement.

In some embodiments, due to the differences in surface energy, hydrophilic/hydrophobic properties, energy gaps, or other characteristics, the first polymer 312 bonded by the thermal conductive material 120 and the second polymer 314 not bonded by the thermal conductive material 120 tend to separately aggregate/accumulate, so as to form a lamellae structure as depicted in FIG. 7C.

In some embodiments, the thermal conductive portions TCA3 with the thermal conductive material 120, exhibit a higher thermal conductivity. On contrary, the thermal insulation portions TIA3 without the thermal conductive material 120 have a lower thermal conductivity. By this arrangement, heat may easily propagate within the thermal conductive portions TCA3 but have limited transmission through the thermal insulation portions TIA3, so that the anisotropic heat conduction material 330 may have anisotropic heat conduction structures ACS3 and thus anisotropic thermal conductivity. In some embodiments, the dry film D31 has a high thermal conductivity (such as, but not limited to, 100 Wm⁻¹K⁻¹ to 250 Wm⁻¹K⁻¹) in a first direction (e.g., a direction substantially perpendicular to the bottom surface of the dry film DF3). In some embodiments, the dry film DF3 has a low thermal conductivity (such as, but not limited to, lower than or equal to about 100 Wm⁻¹K⁻¹) in a second direction (e.g., a direction substantially parallel to the bottom surface of the dry film DF3) different from the first direction. In some embodiments, the difference between the maximum thermal conductivity (in the first direction) and the minimum thermal conductivity (in the second direction) of the dry film DF3 is greater than 10 Wm⁻¹K⁻¹, 20 Wm⁻¹K⁻¹, 30 Wm⁻¹K⁻¹ or more.

In some embodiments, the dry film DF1 in FIG. 2B, the dry film DF2 in FIG. 4B, or the dry film DF3 in FIG. 7B may be used directly as a heat dissipation component and may be formed over or placed over a device such as a semiconductor chip, a package component, or the like, to provide heat dissipation. The details are described as below.

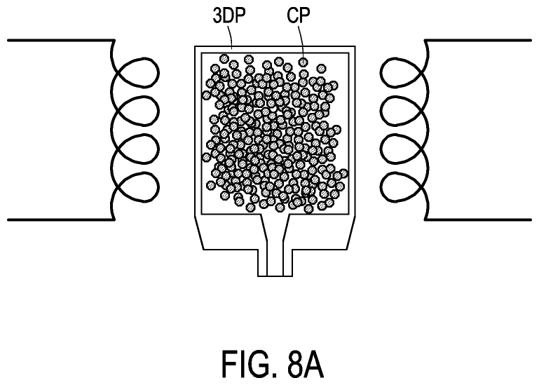

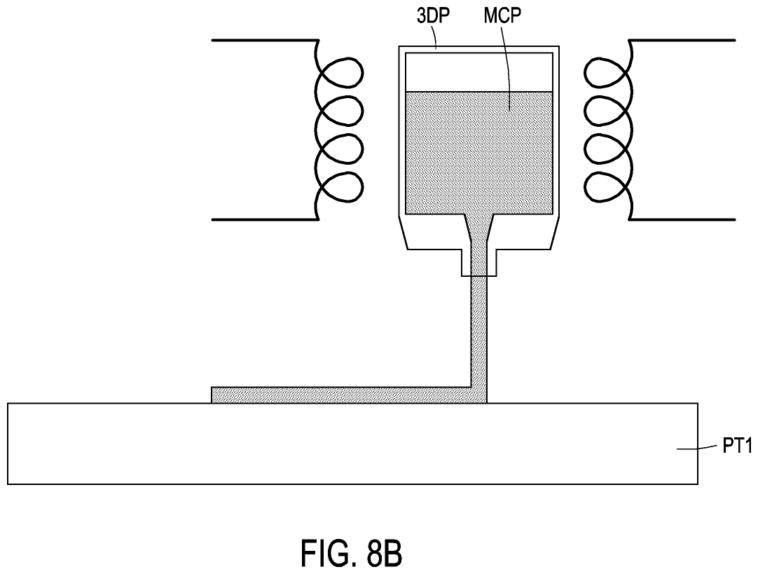

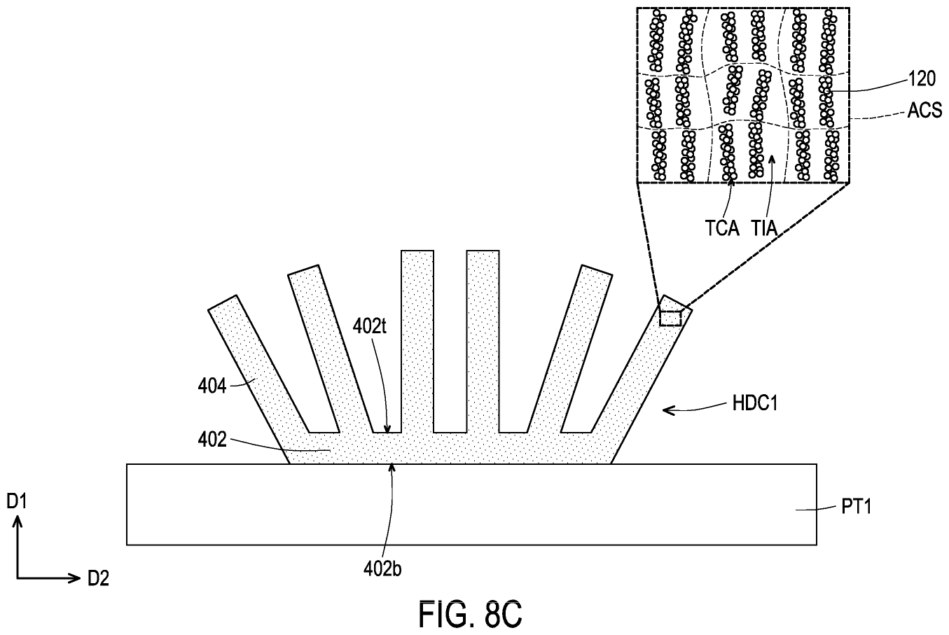

FIGS. 8A to 8C are cross-sectional views illustrating various stages of a manufacturing method of a heat dissipation component in accordance with an embodiment of the present disclosure. Referring to FIG. 8A and optionally step S3 in FIG. 1, after obtaining the dry film (e.g., the dry film DF1 in FIG. 2B, the dry film DF2 in FIG. 4B, or the dry film DF3 in FIG. 7B), the dry film is fragmented to obtain composite pieces CP. For example, the dry film is removed from the platform by scrubbing. As mentioned before, the dry film includes anisotropic heat conduction material obtained by self assembling of a polymeric material and a thermal material, the composite pieces CP also includes anisotropic heat conduction material. In other words, the composite pieces CP respectively may include thermal conductive portions and thermal insulation portions.

Next, by using the composite pieces CP as a raw material, the heat dissipation component is manufactured with 3D printing technology, templated synthesis technology, or other techniques. In some embodiments, as shown in FIG. 8A, the heat dissipation component is produced using 3D printing technology, and therefore the composite pieces CP are placed into the material reservoir of the 3D printer 3DP.

Referring to FIG. 8B and optionally step S4 in FIG. 1, the anisotropic heat conduction material (i.e., the composite pieces CP) is heated, so that the polymeric material within the composite material melt and form a processing material MCP. The processing material MCP may be a paste or a viscous material with low flowability. The heating temperature of the processing material MCP may exceed the glass transition temperature of the polymeric material in the composite material. For example, the glass transition temperature of the polymeric material in the composite material is in a range of 150° C. to 200° C.

Then, the processing material MCP is applied (e.g., extruded) onto the platform PT1, layer by layer, to form a heat dissipation component HDC1 with the desired shape, as shown in FIG. 8C. In some embodiments, due to the adhesive property of the processing material MCP, the heat dissipation component HDC1 may also be directly formed on the device (such as semiconductor chip, package component, or the like) using 3D printing technology.

In some embodiments, since the processing material MCP is in a molten state, the thermal conductive material 120 in the processing material MCP may move during the solidification process of the processing material MCP, contributing to the regular arrangement of the thermal conductive material 120. The heat dissipation component HDC1 may include multiple anisotropic heat conduction structures ACS (or lamellae structures), with each anisotropic heat conduction structure ACS containing alternating arrangements of thermal conductive portions TCA (also referred to as first lamellar portions) and thermal insulation portions TIA (also referred to as second lamellar portions). The thermal conductive portions TCA with the thermal conductive material 120 exhibit higher thermal conductivity. Conversely, the thermal insulation portions TIA without the thermal conductive material 120 have lower thermal conductivity. By this structure, heat may easily propagate within the thermal conductive portions TCA but have limited transmission through the thermal insulation portions TIA, resulting in the anisotropic heat conduction structures ACS having anisotropic thermal conductivity. The anisotropic heat conduction structures ACS in the heat dissipation component HDC1 are similar to the anisotropic heat conduction structures ASC1 in FIGS. 2B and 2C, the anisotropic heat conduction structures ASC2 in FIGS. 4B and 4C, the anisotropic heat conduction structures ASC3 in FIGS. 7B and 7C or the anisotropic heat conduction structures in FIGS. 6B and 6C, depending on the choice of materials.

In some embodiments, the processing material MCP may experience shear forces during the 3D printing process. The shear forces help orient the thermal conductive portions TCA and the thermal insulation portions TIA to extend in a direction substantially perpendicular to the top surface of the platform PT1. In other words, it assists in arranging the thermal conductive portions TCA and thermal insulation portions TIA in the direction substantially parallel to the top surface of the platform PT1. In some cases, heat may be applied to the platform PT1 to promote a more regular arrangement of the heat conduction structures ACS. Furthermore, on the top surface of the platform PT1, increasing the entropy generally reduces surface energy. As a result, the thermal conductive portions TCA and the thermal insulation portions TIA of the anisotropic heat conduction structures ACS that contact the top surface of the platform PT1 tend to arrange in the direction substantially parallel to the top surface of the platform PT1, allowing different materials to contact the top surface of the platform PT1 and thereby increasing the entropy.

There may be grain boundary-like structure between these anisotropic heat conduction structures ACS. The arrangement direction of the thermal conductive portions TCA and thermal insulation portions TIA of each anisotropic heat conduction structure ACS may have a slight deviation from the arrangement direction of the thermal conductive portions TCA and thermal insulation portions TIA of adjacent anisotropic heat conduction structure ACS, but the thermal conductive portions TCA and thermal insulation portions TIA mostly extend upwards. Therefore, the heat dissipation component HDC1 has a higher thermal conductivity in the upward direction D1 (or the direction substantially perpendicular to the bottom surface of the heat dissipation component HDC1) than in the horizontal direction D2 (or the direction substantially parallel to the bottom surface of the heat dissipation component HDC1). In some embodiments, on the bottom surface 402b of the heat dissipation component HDC1 in contact with the platform PT1, there are multiple thermal conductive portions TCA and thermal insulation portions TIA arranged in the horizontal direction D2.

In some embodiments, the heat dissipation component HDC1 is a heat sink including a base 402 and protruding structures 404. The protruding structures 404 are connected to a top surface 402t of the base 402 and extending upward from the top surface 402t of the base 402. The base 402 and the protruding structures 404 include anisotropic heat conduction material and thus have anisotropic heat conduction structures ACS. The base 402 and the protruding structures 404 have a higher thermal conductivity in the direction D1 substantially perpendicular to the top surface 402t of the base 402 than the thermal conductivity in the direction D2 substantially parallel to the top surface 402t of the base 402.

In some embodiments, the protruding structures 404 are fin structures. In some embodiments, the protruding structures 404 extend upward from the top surface 402t of the base 402 in different directions to provide flexibility for heat sink design. The protruding structures 404 may have varying lengths and different extension directions, allowing for more flexible design of the heat dissipation component HDC1. In some embodiments, the polymeric material in the heat dissipation component HDC1 includes elastomers. Therefore, the heat dissipation component HDC1 may serve as a flexible heat sink, and it may undergo deformation when subjected to external forces.

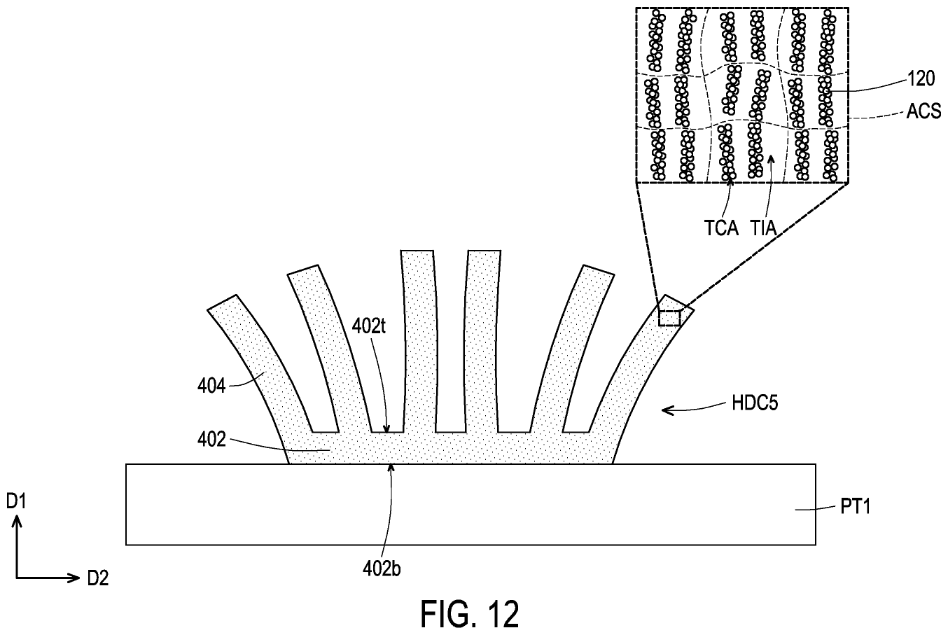

In some embodiments, the protruding structures 404 include sidewalls that are inclined or vertical relative to the top surface 402t of the base 402, but this disclosure is not limited thereto. In alternative embodiments (as shown in FIG. 12), the protruding structures 404 may have curved sidewalls. In other words, the protruding structures 404 may have non-flat surfaces.

In some embodiments, after the completion of 3D printing, the heat dissipation component HDC1 is subjected to additional annealing to achieve a smoother surface. In some embodiments, annealing the heat dissipation component HDC1 to near the glass transition temperature of the polymeric material of the anisotropic heat conduction material helps improve the orientation of the anisotropic heat conduction structures ACS.

In some embodiments, the heat dissipation component HDC1 with the desired shape is formed using the 3D printer 3DP, but the disclosure is not limited thereto. In alternative embodiments, the composite pieces CP (referring to FIG. 8A) are also be heated and used as adhesive materials, thermal grease materials, thermal interface material, and so on.

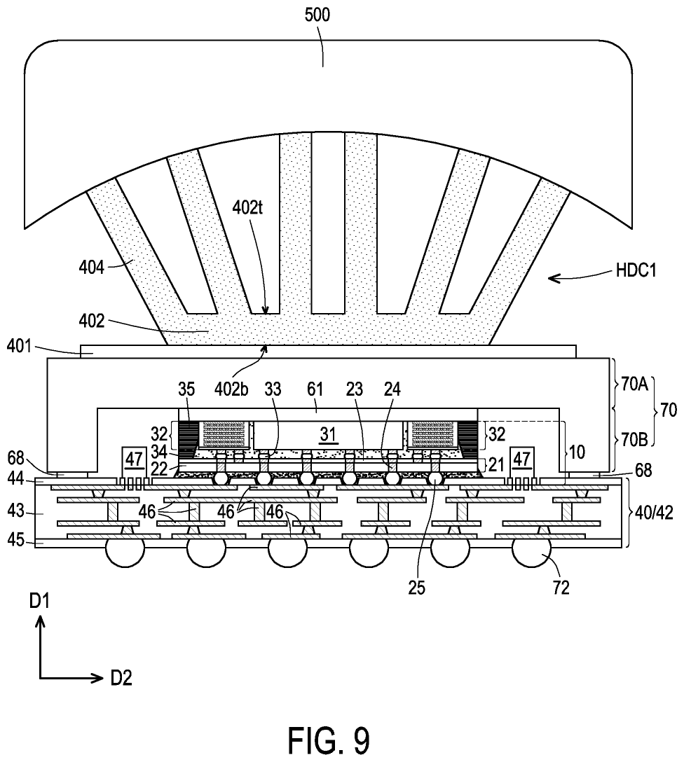

FIG. 9 is a cross-sectional view illustrating a semiconductor device in accordance with an embodiment of the present disclosure. Referring to FIG. 9, a package component 40 is provided, which may contain multiple identical package substrates 42 within it. In some embodiments, the package substrates 42 may be cored package substrates including cores, or may be core-less package substrates that do not have cores therein. In alternative embodiments, the package component 40 might be a different type of component, such as an interposer wafer, a printed circuit board, a reconstructed wafer, and so forth. It may or may not contain active devices like transistors and diodes, as well as passive devices like capacitors, inductors, or resistors.

In some embodiments, the package component 40 includes multiple dielectric layers, including dielectric layers 43, a dielectric layer 44 on top of dielectric layers 43, and a dielectric layer 45 beneath the dielectric layers 43. The dielectric layers 44 and 45, in some cases, may be made of dry films like Ajinomoto Build-up Films (ABFs). Alternatively, they could consist of or incorporate materials such as polybenzoxazole (PBO), polyimide, benzocyclobutene (BCB), and similar materials, which may be applied in a flowable form and subsequently cured. The dielectric layer 43, when used in a core, may consist of materials like epoxy, resin, glass fiber, prepreg (including epoxy, resin, and/or glass fiber), glass, molding compound, plastic, combinations thereof, or multilayers thereof. In alternative embodiments, the dielectric layers 43 could be constructed from polymers such as PBO, polyimide, BCB, or similar materials. Redistribution lines 46, encompassing metal lines, pads, and vias, are embedded within the dielectric layers 43, forming through-connections in the package component 40.

A package 10 is provided over the package component 40, including package components 21, 31, and 32. In some embodiments, the package component 21 serves as an interposer and includes a substrate 22 and corresponding dielectric layer(s) 23. Therefore, the package component 21 may also be referred to as an interposer 21, although other types of package components 21 are also possible. The schematic illustration of the interposer 21 does not show detailed features such as the dielectric layers(s) 23 on the top and bottom sides of the substrate 22, metal lines, vias, metal pads, and other elements. Through-substrate vias 24, referred to as through-silicon vias 24 when the substrate 22 is made of silicon, penetrate through the substrate 22 and are used for interconnecting conductive features on both sides of the substrate 22. Solder regions 25, which may underlie and be joined to interposers, serve to bond the interposers 21 to the package component 40. Alternatively, other bonding schemes such as metal-to-metal direct bonding or hybrid bonding may also be employed for bonding package components 21 to package component 40.

In certain embodiments, the package components 31 and 32 are attached to their respective underlying package component 21. FIG. 9 presents a cross-sectional view displaying one package component 31 and two package components 32, all bonded to the same package component 21. However, the actual quantity of package components 31 and 32 may be adjusted as needed.

Each of the package components 31 and 32 may be a device die, a package with a device die(s) packaged therein, a System-on-Chip (SoC) die including a plurality of integrated circuits (or device dies) integrated as a system, or the like. The device dies within the package components 31 and 32 may be or may include logic dies, memory dies, input-output dies, Integrated Passive Devices (IPDs), or the like, or combinations thereof. For example, the logic device dies in the package components 31 and 32 could be Central Processing Unit (CPU) dies, Graphic Processing Unit (GPU) dies, mobile application dies, Micro Control Unit (MCU) dies, BaseBand (BB) dies, Application processor (AP) dies, and so on. The memory dies in package components 31 and 32 might include Static Random Access Memory (SRAM) dies, Dynamic Random Access Memory (DRAM) dies, and others.

In the subsequent discussion, based on certain example embodiments, the package component 31 is referred to as device dies, which could be SoC dies in some scenarios. On the other hand, the package components 32 could represent memory stacks like High-Performance Memory (HBM) stacks. The package components 32 may include memory dies organized into a die stack, with an encapsulant (such as a molding compound) enclosing the memory dies.

The package components 31 and 32 are bonded to the underlying package component 21, often through solder regions 33. An underfill material 34 is dispensed between the package components 31 and 32 and the underlying package component 21. In some embodiments, the package 10 is created using a Chip-on-Wafer (CoW) bonding process. In this process, discrete chips/packages like package components 31 and 32 are bonded to package component 21 that remain in an unsawed wafer, forming a reconstructed wafer. After applying underfills 34, an encapsulant, such as molding compound 35, may be added. A planarization process is carried out on the molding compound 35 to level its top surface with the top surfaces of package components 31 and 32. This results in the formation of a reconstructed wafer, which is then sawed into separate packages 10, each of which is bonded to the package component 40.

There may be other package components such as Independent Passive Devices (IPDs) 47 bonded to the package component 40. In accordance with some embodiments, the IPDs 47 are discrete components, including capacitors, inductors, resistors, or similar elements, and they do not contain active devices like transistors.

A Thermal Interface Material (TIM) 61 is applying onto the package 10. While one TIM 61 is depicted, there may be one, two, or more of the TIM 61 disposed on the same package 10. The TIM 61 is in the form of a film-type TIM, meaning it is a pre-formed solid TIM when it is attached to the package 10. This is in contrast to liquid-type TIMs that are dispensed in a flowable state and then cured into a solid form. The TIM 61 may be either rigid and attached through a picking and placing process, or it may be a flexible film rolled into place and then pushed onto the package 10. In some embodiments, the TIM 61 makes contact with the top surface of the package components 31 and 32.

An adhesive 68 is applied to the top surface of package component 40. The adhesives 68 may be dispensed in a manner that forms a ring encircling the package 10, or they may be dispensed as separate portions aligned in a ring-like pattern. The thermal conductivity of the adhesive 68 may be lower than that of the TIM 61. For instance, the adhesive 68 may have a thermal conductivity value lower than approximately 1 W/k*m, although higher thermal conductivity values are possible.

A lid 70 is disposed on the TIM 61 over the package component 40. In some embodiments, when the package component 40 is at the wafer-level and includes multiple package components 42, there are multiple lids 70, each attached to one of the package components 42. In some embodiments, the lid 70 is made of metal or other thermally conductive materials.

The lid 70 includes an upper portion 70A with a flat bottom surface in contact with the TIM 61. The lid 70 may also incorporate a lower portion (skirt) 70B that extends downward to adhere to the adhesive 68 in certain embodiments. The lower portion 70B may form a complete ring encircling package 10. However, in alternative embodiments, the lid 70 may not include the lower portion 70B. Consequently, the adhesive dispensing process depicted may be omitted in these cases.

The heat dissipation component HDC1 is placed over the top surface of the package 10. In some embodiments, the heat dissipation component HDC1 is attached to the lid 70 and covers the package component 31 (e.g., the die). In some embodiments, the heat dissipation component HDC1 is attached to the lid 70 through an adhesive layer 401, but this disclosure is not limited thereto. In alternative embodiments, the heat dissipation component HDC1 is directly formed on the lid 70, and the adhesive layer 401 may be omitted. The lid 70 is disposed between the package component 31 and the heat dissipation component HDC1.

Due to the presence of heat conduction structures formed through self-assembly of the polymeric material and the thermal conductive material in the heat dissipation component HDC1, the heat dissipation component HDC1 has the thermal conductivity in the direction D1 substantially perpendicular to the top surface of the package component 31 higher than the thermal conductivity in a direction D2 substantially parallel to the top surface of the package component 31.

In some embodiments, an external component 500 is disposed on the heat dissipation component HDC1. In certain embodiments, one side of the external component 500 facing the heat dissipation component HDC1 may be a non-planar surface (e.g., it may be a curved surface). Because the heat dissipation component HDC1 is flexible and has the protruding structures 404 with different directions/lengths, it may more easily match the non-planar surface of the external component 500 in some embodiments.

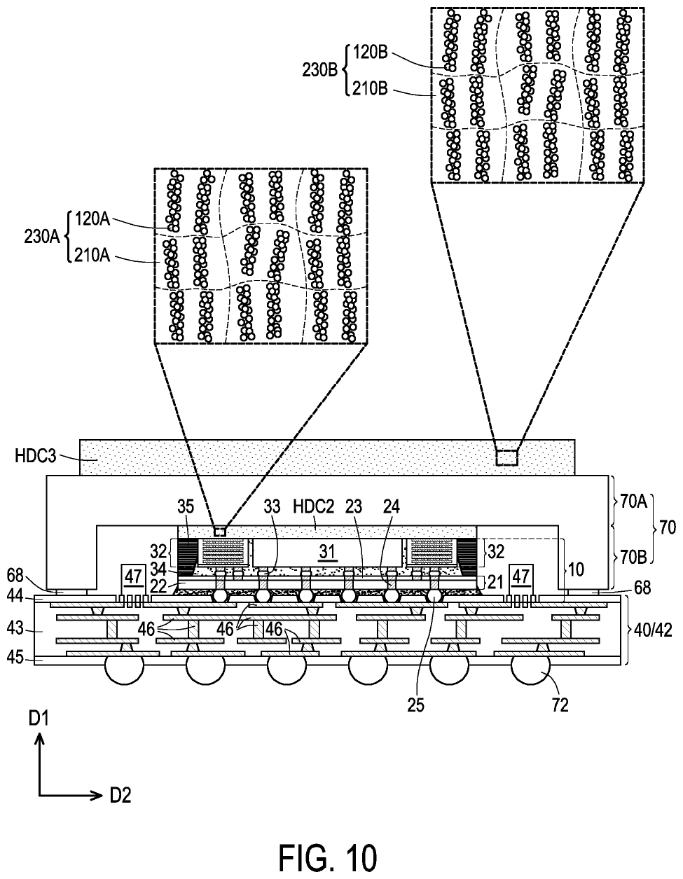

FIG. 10 is a cross-sectional view illustrating a semiconductor device in accordance with an embodiment of the present disclosure. It should be noted herein that, in embodiments provided in FIG. 10, element numerals and partial content of the embodiments provided in FIG. 9 are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 10, in some embodiments, the heat dissipation component HDC2 is directly formed on the package 10. For example, the heat dissipation component HDC2 is directly formed on the package components 31 and 32, as well as the molding compound 35. The heat dissipation component HDC2 may serve as a TIM and is used to bond the lid 70 to the package 10. In some embodiments, the heat dissipation component HDC2 is a pre-formed solid TIM when it is attached to package 10. The heat dissipation component HDC3 is formed on the lid 70 and over the package components 31 and 32. In some embodiments, the heat dissipation component HDC3 is sheet-like. In some embodiments, the heat dissipation component HDC3 is a pre-formed solid sheet that is then attached to the lid 70.

The heat dissipation component HDC2, HFC3 respectively include an anisotropic heat conduction material 230A, 230B including polymeric material 210A, 210B and the thermal conductive material 120A, 120B. The polymeric material 210A, 210B and the thermal conductive material 120A, 120B are formed through self-assembly to create anisotropic heat conduction structures. The anisotropic heat conduction structures formed by the polymeric material 210A, 120B and the thermal conductive material 120A, 120B have a similar or identical structure and manufacturing method as described in previous sections for the anisotropic heat conduction structures ASC1 in FIGS. 2B and 2C, the anisotropic heat conduction structures ASC2 in FIGS. 4B and 4C, the anisotropic heat conduction structures ASC3 in FIGS. 7B and 7C or the anisotropic heat conduction structures in FIGS. 6B and 6C. In some embodiments, depending on different purposes, the anisotropic heat conduction material 230B and the anisotropic heat conduction material 230A may include the same or different materials.

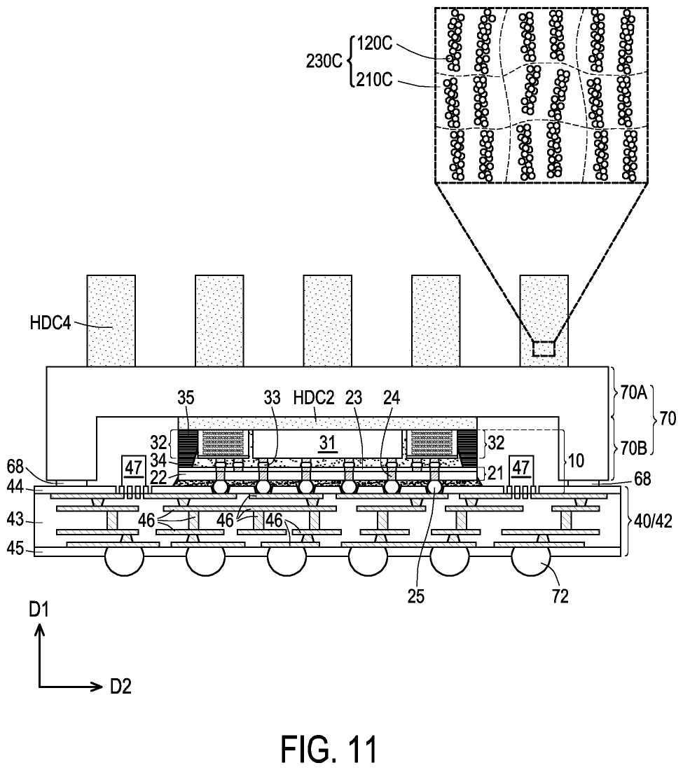

FIG. 11 is a cross-sectional view illustrating a semiconductor device in accordance with an embodiment of the present disclosure. It should be noted herein that, in embodiments provided in FIG. 11, element numerals and partial content of the embodiments provided in FIG. 10 are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 11, in some embodiments, the heat dissipation component HDC4 is formed on the lid 70 and over the package components 31 and 32. In some embodiments, the heat dissipation component HDC4 includes fin structures. The material of the fin structure includes an anisotropic heat conduction material 230C.

The anisotropic heat conduction material 230C including a polymeric material 210C and the thermal conductive material 120C. The polymeric material 210C and the thermal conductive material 120C are formed through self-assembly to create anisotropic heat conduction structures. The anisotropic heat conduction structures formed by the polymeric material 210C and the thermal conductive material 120C have a similar or identical structure and manufacturing method as described in previous sections for the anisotropic heat conduction structures ASC1 in FIGS. 2B and 2C, the anisotropic heat conduction structures ASC2 in FIGS. 4B and 4C, the anisotropic heat conduction structures ASC3 in FIGS. 7B and 7C or the anisotropic heat conduction structures in FIGS. 6B and 6C. In some embodiments, depending on different purposes, the anisotropic heat conduction material 230C of the heat dissipation component HDC4 may be the same or different from the anisotropic heat conduction material 230A of the heat dissipation component HDC2.

FIG. 12 is a cross-sectional view illustrating a heat dissipation component HDC 5 in accordance with an embodiment of the present disclosure. The material and manufacturing process of the heat dissipation component HDC5 in FIG. 12 may be similar to those of the heat dissipation component HDC1 in FIG. 8C, and the difference lies in that at least some of the protruding structures 404 in the heat dissipation component HDC5 have curved sidewalls.

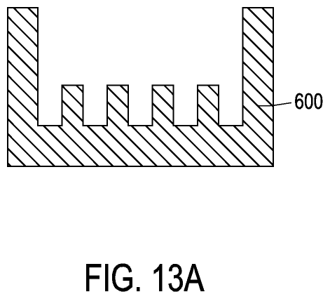

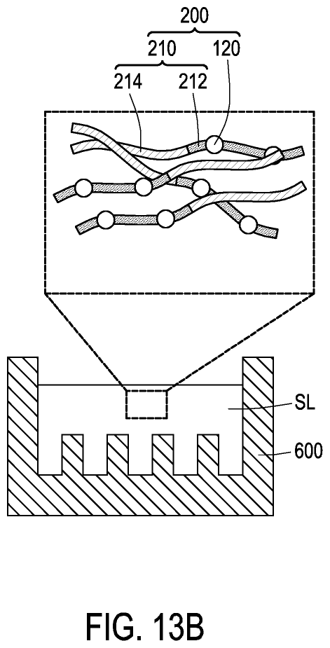

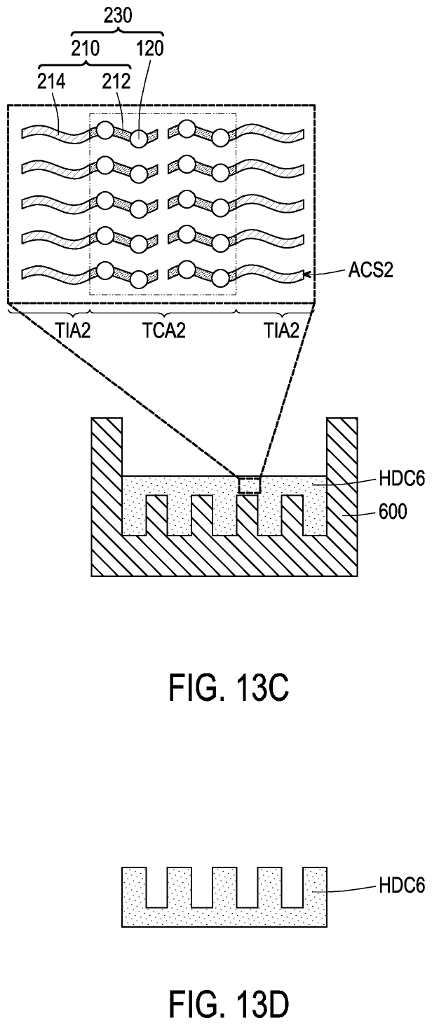

FIGS. 13A to 13D are cross-sectional views illustrating various stages of a manufacturing method of a heat dissipation component in accordance with an embodiment of the present disclosure. In the embodiments shown in FIGS. 13A to 13D, a templated synthesis technology is used to determine the shape of the heat dissipation component.

In FIGS. 13A and 13B, a polymeric material 210 and a thermal conductive material 120 are mixed in a solvent SL to obtain a composite material 200. The polymeric material 210, the thermal conductive material 120, and the solvent SL are filled into the mold 600. Further details about the composite material 200 may be found in the above paragraphs related to FIGS. 4A to 4C. In some embodiments, the composite material 200 is used as an example, but this disclosure is not limited thereto. In alternative embodiments, the composite material 100 (as shown in FIG. 2A) or the composite material 300 (as shown in FIG. 7A) may be filled into the mold 600.

In FIG. 13C, the solvent SL in the mold 600 evaporates. The polymeric material 210 and the thermal conductive material 120 self-assemble to form an anisotropic heat conduction material 230. The heat dissipation component HDC6 is defined in shape by the mold 600 and includes the anisotropic heat conduction material 230 with the anisotropic heat conduction structures ACS2. In some embodiments, an annealing process is performed to enhance the stability of the heat dissipation component HDC6.

In some embodiments, the materials containing the solvent SL is applied into the mold 600, but this disclosure is not limited thereto. In alternative embodiments, a dry film is first formed. That is, after obtaining the dry film (e.g., the dry film DF1 in FIG. 2B, the dry film DF2 in FIG. 4B, or the dry film DF3 in FIG. 7B), the dry film is fragmented to obtain composite pieces. The composite pieces are then melted and filled into the mold 600. The heat dissipation component HDC6 may be obtained by curing the composite pieces in the mold 600.

Referring to FIG. 13D, the heat dissipation component HDC6 is picked up from the mold 600.

As the semiconductor devices continue towards smaller size and enhanced performance, the temperature of the semiconductor devices may rise. For example, in the complementary field-effect transistor (CFET), thermal cross talk becomes an even more critical issue. In some embodiments, the heat sink component has the anisotropic heat conduction material, and thus the heat sink component may have heat dissipation in different directions. Accordingly, the semiconductor device including the heat sink component may have improved reliability and lifespan. For example, the heat dissipation component may include multiple protruding structures, with the thermal conductivity in the vertical direction being higher to that in the horizontal direction. This enables more efficient heat dissipation, preventing heat accumulation between the protruding structures. Furthermore, since the anisotropic heat conduction material is flexible, the anisotropic heat conduction material may be shaped as needed, in other words, the heat sink component may have desirable shape.

According to some embodiments, a heat dissipation component includes an anisotropic heat conduction material. The anisotropic heat conduction material includes a polymeric material and a thermal conductive material. First portions of the polymeric material are bonded by the thermal conductive material and form thermal conductive portions. Second portions of the polymeric material not bonded by the thermal conductive material form thermal insulation portions. The thermal conductive portions and the thermal insulation portions are alternately arranged.

According to some embodiments, a semiconductor device includes a die and a heat dissipation component. The heat dissipation component is disposed over the die. The heat dissipation component includes an anisotropic heat conduction material including first lamellar portions and second lamellar portions arranged alternately. Thermal conductivity of the first lamellar portions is higher than thermal conductivity of the second lamellar portions.

According to some embodiments, a method of fabricating a heat dissipation component includes the following steps. A polymeric material and a thermal conductive material are mixed in a solvent to obtain a composite material. The composite material is solution casted. During an evaporation of the solvent, the polymeric material and the thermal conductive material self-assemble to form an anisotropic heat conduction material having thermal conductive portions and thermal insulation portions alternately arranged.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A heat dissipation component, comprising:
an anisotropic heat conduction material, comprising a polymeric material and a thermal conductive material,
wherein first portions of the polymeric material are bonded by the thermal conductive material and form thermal conductive portions, second portions of the polymeric material not bonded by the thermal conductive material form thermal insulation portions, and the thermal conductive portions and the thermal insulation portions are alternately arranged.

2. The heat dissipation component of claim 1, wherein the polymeric material comprises homopolymer.

3. The heat dissipation component of claim 1, wherein the polymeric material comprises copolymer, the first portions of the polymeric material comprise a first structural unit of the copolymer, and the second portions of the polymeric material comprises a second structural unit of the copolymer.

4. The heat dissipation component of claim 1, wherein the polymeric material comprises polymer blends, the first portions of the polymeric material comprise a first polymer of the polymer blends, and the second portions of the polymeric material comprise a second polymer of the polymer blends.

5. The heat dissipation component of claim 1, wherein the polymeric material comprises polyethylene, poly(vinylidene fluoride), polylactide, polydiacetylene, polycarbonate, polyolefin, polythiophene, poly(3-hexylthiophene), polyurethane, fluorene polyester, polyimide, divinyltetramethyldisiloxane-bis(benzocyclobutene) or a combination thereof.

6. The heat dissipation component of claim 1, wherein the thermal conductive material comprises copper, silver, graphene, silicon oxide, hexagonal boron nitride, silicon carbide, diamond or a combination thereof.

7. The heat dissipation component of claim 1, wherein the thermal conductive portions and the thermal insulation portions are alternately arranged along a horizontal direction.

8. A semiconductor device, comprising:
a die; and
a heat dissipation component over the die, comprising an anisotropic heat conduction material, wherein the anisotropic heat conduction material comprises a plurality of first lamellar portions and a plurality of second lamellar portions arranged alternately, and thermal conductivity of the first lamellar portions is higher than thermal conductivity of the second lamellar portions.

9. The semiconductor device of claim 8, wherein the heat dissipation component is stacked over the die along a first direction, and the first lamellar portions and the second lamellar portions are arranged alternately along a second direction substantially perpendicular to the first direction.

10. The semiconductor device of claim 8, wherein the heat dissipation component comprises a plurality of protrusion structures, and the protrusion structures extend along different directions.

11. The semiconductor device of claim 10, wherein the protrusion structures respectively have a linear sidewall or a curved sidewall.

12. The semiconductor device of claim 10, further comprising an external component, wherein the heat dissipation component is disposed between the external component and the die, and the external component has a curved surface being in direct contact with the protrusion structures.

13. The semiconductor device of claim 8, wherein the heat dissipation component comprises a plurality of fin structures, and the fin structures extend along a direction substantially perpendicular to a surface of the die.

14. The semiconductor device of claim 8, wherein the heat dissipation component comprises a heat sink.

15. A method of fabricating a heat dissipation component, comprises:
mixing a polymeric material and a thermal conductive material in a solvent to obtain a composite material; and
solution casting the composite material, wherein during an evaporation of the solvent, the polymeric material and the thermal conductive material self-assemble to form an anisotropic heat conduction material, wherein the anisotropic heat conduction material comprises a plurality of thermal conductive portions and a plurality of thermal insulation portions alternately arranged.

16. The method of claim 15, further comprising:
drying the composite material to obtain a dry film;
fragmenting the dry film to obtain composite pieces;
heating the composite pieces to obtain a processing material; and
shaping the processing material using a mold or 3D printing.

17. The method of claim 15, wherein the polymeric material comprises homopolymer, the thermal conductive material is bonding to first portions of the homopolymer to form the thermal conductive portions, and second portions of the homopolymer not bonded by the thermal conductive material form the thermal insulation portions.

18. The method of claim 15, wherein the polymeric material comprises copolymer including a first structural unit and a second structural unit, the thermal conductive material is bonding to the first structural unit to form the thermal conductive portions, and the second structural unit not bonded by the thermal conductive material forms the thermal insulation portions.

19. The method of claim 15, wherein the polymeric material comprises polymer blends, the thermal conductive material is bonding to a first polymer of the polymer blends, and a second polymer of the polymer blends not bonded by the thermal conductive material forms the thermal insulation portions.

20. The method of claim 15, wherein the thermal conductive material comprises copper, silver, graphene, silicon oxide, hexagonal boron nitride, silicon carbide, diamond or a combination thereof.
